(19) United States
(12) Patent Application Publication
(10) Pub. No.: US 2007/0023772 A1
(43) Pub. Date: Feb. 1, 2007

(54) Semiconductor light-emitting device and method of manufacturing same

(75) Inventors: Nobuyuki Watanabe, Nara-shi (JP); Yukari Inoguchi, Kanmaki-cho (JP); Tetsuroh Murakami, Tenri-Shi (JP)

Correspondence Address: MORRISON & FOERSTER LLP, 1650 TYSONS BOULEVARD, SUITE 300, MCLEAN, VA, 22102, US

(73) Assignee: SHARP KABUSHIKI KAISHA, Osaka-shi (JP)

(21) Appl. No.: 11/492,045

(22) Filed: Jul. 25, 2006

(30) Foreign Application Priority Data
Jul. 26, 2005 (JP) 2005-215797
May 22, 2006 (JP) 2006-141856

(51) Int. Cl. H01L 33/00

(52) U.S. Cl. 257/94

(57) ABSTRACT

A semiconductor light-emitting device has a first conductivity type semiconductor layer (3, 4), a luminous layer (5) formed on the first conductivity type semiconductor layer, a second conductivity type semiconductor layer (8) formed on the luminous layer, and a transmissive substrate (9) which is formed on the second conductivity type semiconductor layer (8) and is pervious to light coming from the luminous layer (5). The transmissive substrate (9) has a carrier concentration lower than that of the second conductivity type semiconductor layer (8).

This nonprovisional application claims priority under 35 U.S.C. §119(a) on Patent Application Nos. 2005-215797 and 2006-141856 filed in Japan on Jul. 26, 2005 and May 22, 2006, the entire contents of which are hereby incorporated by reference.

### BACKGROUND OF THE INVENTION

The present invention relates to a semiconductor light-emitting device which is an illuminant used for, for example, a communication device, a road, rail way, or guide display panel device, an advertisement display device, a mobile telephone, a display backlight, lighting equipment, or the like, and a method of manufacturing the semiconductor light-emitting device.

In recent years, technologies of manufacturing a semiconductor light-emitting diode (referred to as an “LED” hereinafter), which is one of semiconductor light-emitting devices, have rapidly progressed, and in particular, LEDs for primary colors of light have been completed after the blue LED was developed, so that it has become possible to produce light of every wavelength by combinations of LEDs for primary colors of light. As a result of this, the scope of application of LEDs has been rapidly widened, and in particular, in the field of lighting, attention is being given to an LED as a natural-light or white-light source which is an alternative to an electric bulb or fluorescent lamp, with the increase of awareness of environmental and energy issues.

However, current LEDs are inferior in efficiency of conversion of applied energy into light as compared with an electric bulb or fluorescent lamp, and therefore research aimed at developing LEDs having a higher conversion efficiency and higher luminance has been underway whatever their wavelengths.

Until a decade ago, the focus of the research and development of a higher luminance LED has been on epitaxial growth technologies. However, in recent years when the technologies have matured, the focus is being sifted to the development which centers on process technologies.

Increase in luminance by a process technology means increase in external quantum efficiency (i.e., an internal quantum efficiency multiplied by an external extraction efficiency), and specifically there are process technologies such as technologies for micromachining the shape of an LED, providing reflecting films and transparent electrodes, etc. Among others, some techniques of increasing the luminance by wafer bonding have been established for red and blue LEDs, and high luminance LEDs were invented and have appeared on the market.

Techniques of increasing the luminance by wafer bonding are broadly classified into two types. One is a technique of attaching an opaque substrate such as a silicon substrate or a germanium substrate to an epitaxial layer directly or via a metallic layer. The other one is a technique of attaching a substrate transparent to an emission wavelength, such as a glass substrate, a sapphire substrate, or a GaP substrate, to an epitaxial layer directly or via a bonding layer.

FIG. 1 is a schematic cross-sectional view of an LED for which the former technique was used. FIG. 2 is a schematic cross-sectional view of an LED for which the latter technique was used.

In FIG. 1, the reference numerals 101 and 103 denote epitaxial layers, 102 denotes a luminous layer, 104 denotes a metallic layer for reflection, 105 denotes a silicon substrate, and 106 and 107 denote electrodes.

In the LED in FIG. 1, light L emitted from the luminous layer 103 is reflected to the outside by the metallic layer for reflection 104 as shown by the arrows before being absorbed by the silicon substrate 105.

In FIG. 2, the reference numeral 201 denotes a window layer, 202 and 204 denote epitaxial layers, 203 denotes a luminous layer, 205 denotes a transparent substrate, and 206 and 207 denote electrodes.

In the LED in FIG. 2, light L emitted from the luminous layer 203 passes through as shown by the arrows without being absorbed by the transparent substrate 205.

In particular, in the LED for which the technique of attaching the transparent substrate 205 to the epitaxial layer 204 is used, light emitted from the luminous layer 203 can be extracted from almost every surface of the LED without passing through the luminous layer 203 again, in other words, without being absorbed by the luminous layer 203. It is therefore possible to develop an LED having a higher conversion efficiency (light extraction efficiency).

One of conventional techniques of attaching a transparent substrate to an epitaxial layer is described in JP 3230638 B2. In the technique described in JP 3230638 B2, a GaP (gallium phosphorus) transparent substrate is attached directly to an AlGaInP (aluminum gallium indium phosphorus) semiconductor layer in order to make a 4-element LED.

By the way, in the technique of attaching a transparent substrate to an epitaxial layer as described above, the transparent substrate is attached directly to the epitaxial layer in order to improve the light transparency. In this case, since the resistance of the interface between the transparent substrate and the epitaxial layer, i.e. the attaching interface, is large, there is a problem that the driving voltage of the LED increases.

It is conceivable that a solution to the problem is to increase the carrier concentration of the transparent substrate to reduce the resistance of the attaching interface. However, when the carrier concentration of the transparent substrate is increased, the absorption and/or attenuation of light will easily occur in the transparent substrate having the increased high carrier concentration.

As a result of this, in the LED with the transparent substrate having the increased carrier concentration, the problem arises that the light extraction efficiency decreases. The absorption of light arising at this time is mainly caused by the free carriers and substantially irrespective of the band gap of the crystal.

Furthermore, when the carrier concentration of the transparent substrate is increased, the densities of impurities and/or defects in the transparent substrate increase as a matter of course, so that the light is absorbed and/or attenuated by the impurities and/or the defects.

Furthermore, in the technique of attaching the transparent substrate to the epitaxial layer, heat treatment is carried out in order to attach the transparent substrate to the epitaxial layer. Since the heat treatment is carried out at a high temperature, the atoms, which are dopant, are diffused and segregated to the attaching interface, the crystal interface, the luminous layer, etc.

When the atoms, which are dopant, are segregated to the attaching interface and the crystal interface, the light transmittances at the attaching interface and the crystal interface deteriorate, and when the atoms, which are dopant, are segregated to the luminous layer, the luminous efficiency of the luminous layer decreases.

Also when a metallic layer is provided at the attaching interface for the purpose of reducing the resistance of the attaching interface, the metallic layer itself is not usually transmissive, or pervious to light, and when heat treatment or the like is carried out in order to improve the contact of the interface between the metal and the crystal, an alloy layer at the interface becomes a light-absorption layer (darkening). As a result of this, increase in the efficiency of external extraction of light is not much expected.

### SUMMARY OF THE INVENTION

It is therefore an object of the present invention to provide a semiconductor light-emitting device having an increased light extraction efficiency, and a method of manufacturing the semiconductor light-emitting device.

In order to solve the problem, a semiconductor light-emitting device according to an aspect of the present invention includes:

a first conductivity type semiconductor layer;

a luminous layer formed on the first conductivity type semiconductor layer;

a second conductivity type semiconductor layer formed on the luminous layer; and

a transmissive substrate which is formed on the second conductivity type semiconductor layer and is transmissive to light coming from the luminous layer, wherein

the second conductivity type semiconductor layer and the transmissive substrate have their respective carrier concentrations and the carrier concentration of the transmissive substrate is lower than the carrier concentration of the second conductivity type semiconductor layer.

In the present invention, the “first conductivity type” means a p type or an n type, and the “second conductivity type” means the n type when the first conductivity type is the p type, and means the p type when the first conductivity type is the n type.

Ordinary ways of mounting the transmissive substrate include, for example, heat treatment. When heat treatment is carried out to mount the transmissive substrate, if the carrier concentration of the transmissive substrate is higher than that of the second conductivity type semiconductor layer, dopants in the transmissive substrate are diffused toward the second conductivity type semiconductor layer, and are segregated toward the interface between the transmissive substrate and the second conductivity type semiconductor layer, the luminous layer, and/or the like. If the dopants are segregated to the interface between the transmissive substrate and the second conductivity type semiconductor layer, the light transmittance of the interface deteriorates. If the dopants are segregated to the luminous layer, the luminous efficiency of the luminous layer decreases.

FIGS. 3A and 3B show results of analysis by secondary ion mass spectroscopy (SIMS) with respect to the segregation of dopants to the attaching interface of a GaP substrate which is an example of the transmissive substrate, recognized when the GaP substrate is attached to a GaAlInP LED structure. FIG. 3A is a graph showing the distribution of zinc concentration in the depth direction at the attaching interface of a high-concentration GaP substrate having a carrier concentration of 1.5×10¹⁸ cm³, and FIG. 3B is a graph showing the distribution of zinc concentration in the depth direction at the attaching interface of a low-concentration GaP substrate having a carrier concentration of 5.0×10¹⁷ cm⁻³.

As can be seen from FIGS. 3A and 3B, it is recognized that the amount of dopants segregated to the attaching interface depends on the carrier concentration of the GaP substrate, and when the carrier concentration of the GaP substrate is high, the dopants are significantly segregated.

Consequently, by making the carrier concentration of the transmissive substrate lower than that of the second conductivity type semiconductor layer, the diffusion of dopants from the transmissive substrate to the second conductivity type semiconductor layer is reduced (it is apparent from the viewpoint of thermodynamic stability that dopants diffuse from the high concentration side toward the low concentration side), and the light extraction efficiency is therefore increased.

As a result of this, the factors responsible for the reduced luminance of the semiconductor light-emitting device are eliminated, so that it is possible to increase the luminance of the semiconductor light-emitting device.

Furthermore, in mounting the transmissive substrate, as far as the light from the luminous layer is able to pass through the whole or part of the interface between the transmissive substrate and the second conductivity type semiconductor layer, the transmissive substrate may be attached to the second conductivity type semiconductor directly or indirectly via a bond or adhesive, metal, oxide, nitride, or the like.

In one embodiment, the carrier concentration of the transmissive substrate is 2.5×10¹⁸ cm⁻³ or less.

In this embodiment, the driving voltage can be prevented from increasing.

FIGS. 4 and 5 show experimental results about a p-type GaP substrate having the carrier concentration of 1.5×10¹⁸ cm⁻³ and a p-type GaP substrate having the carrier concentration of 5.0×10¹⁷ cm⁻³ (which are represented as a high-concentration GaP substrate and a low-concentration GaP substrate, respectively, in FIGS. 4 and 5). The p-type GaP substrates were doped with zinc.

FIG. 4 shows the results of the p-type GaP substrates' own light transmittances. In the results, the reflection of incident light at the interfaces is not taken into account, so that the light transmittances at the lower energy side than the band gap are in the neighborhood of 50% (actual light transmittances are approximately 90% or more).

There is only a few-percent difference in light transmittance between the p-type GaP substrate having the carrier concentration of 1.5×10¹⁸ cm⁻³ and the p-type GaP substrate having the carrier concentration of 5.0×10¹⁷ cm⁻³, because the thickness of each of the substrates is as small as about 250 μm. Based on this result and the general formula for obtaining a light transmittance which is
I/Iₒ=exp(−αd)
where Iₒ is the initial quantity of light, I is the quantity of transmitted light, d is the thickness, and α is the absorption coefficient, and in consideration of up to the secondary reflection with regard to the light with the wavelength of 640 nm, the absorption coefficient α of the p-type GaP substrate having the carrier concentration of 1.5×10¹⁸ cm⁻³ was calculated as 3.299 cm⁻¹, and the absorption coefficient α of the p-type GaP substrate having the carrier concentration of 5.0×10¹⁷ cm⁻³ was calculated as 5.46×10⁻² cm⁻¹.

Next, the thickness dependence of light transmittance in the case that light passes through the substrate having the absorption coefficient α of 3.299 cm⁻¹ and the thickness dependence of light transmittance in the case that light passes through the substrate having the absorption coefficient α of 5.46×10⁻² cm⁻¹ were calculated. As a result, as shown in FIG. 5, as a matter of course, the longer distance the light travels, the more it attenuates.

When the p-type GaP substrate is mounted on or above the luminous layer, part of the light emitted from the luminous layer is extracted directly to the outside, while another part of the light is reflected by the interface between the substrate crystal/materials and the outside, but most of the light is reflected repeatedly in the p-type GaP substrate.

Thus, it is apparent that most of the light travels a larger distance than the thickness of the p-type GaP substrate. And, with the increasing number of paths of light, the light attenuates more and the efficiency of external extraction of the light decreases.

It becomes possible to reduce such attenuation as far as possible by setting the carrier concentration according to the present invention.

Since the absorption and attenuation of light are mainly caused by free carriers, the setting of the carrier concentration according to the present invention can be applied to any crystal, compound, and material regardless of the kind of substrate, dopant, or the like.

The p-type GaP substrate having the carrier concentration of 1.5×10¹⁸ cm⁻³ was directly attached to a semiconductor layer to make a red semiconductor light-emitting device with the wavelength of 640 nm, and the p-type GaP substrate having the carrier concentration of 5.0×10¹⁷ cm⁻³ was directly attached to a semiconductor layer to make a red semiconductor light-emitting device with the wavelength of 640 nm.

The optical output of the red semiconductor light-emitting device including the p-type GaP substrate having the carrier concentration of 5.0×10¹⁷ cm⁻³ was about 1.5 times that of the red semiconductor light-emitting device including the p-type GaP substrate having the carrier concentration of 1.5×10¹⁸ cm⁻³.

Specifically, the optical output of the red semiconductor light-emitting device including the p-type GaP substrate having the carrier concentration of 5.0×10¹⁷ cm⁻³ was 5.6 mW (the wavelength was 640 nm, and the dominant wavelength was 626 nm), while the optical output of the red semiconductor light-emitting device including the p-type GaP substrate having the carrier concentration of 1.5×10¹⁸ cm⁻³ was 3.8 mW (the wavelength was 640 nm, and the dominant wavelength was 626 nm).

Furthermore, the radiation patterns of the devices were recognized as shown in FIGS. 6A and 6B. FIG. 6A shows the radiation pattern of the red semiconductor light-emitting device including the high carrier concentration p-type GaP substrate, and FIG. 6B shows the radiation pattern of the red semiconductor light-emitting device including the low carrier concentration p-type GaP substrate. From these figures, it was confirmed that the components of light emitted from the lateral sides (p-type Gap substrate) of the red semiconductor light-emitting device including the p-type GaP substrate having the carrier concentration of 5.0×10¹⁷ cm⁻³ (FIG. 6B) were more than those of the red semiconductor light-emitting device including the p-type GaP substrate having the carrier concentration of 1.5×10¹⁸ cm⁻³ (FIG. 6A).

In one embodiment, the carrier concentration of the second conductivity type semiconductor layer is between 5.0×10¹⁷ cm⁻³ and 5.0×10¹⁸ cm⁻³, inclusive.

In this embodiment, the light extraction efficiency can be further increased.

The carrier concentration of the second conductivity type semiconductor layer can be freely selected from the range of 5.0×10¹⁷ cm⁻³ to 5.0×10¹⁸ cm⁻³ as far as the selected concentration is lower than the carrier concentration of the transmissive substrate.

In one embodiment, at least part of the transmissive substrate is made of a second conductivity type semiconductor or a second conductivity type electric conductor.

In this embodiment, the transmissive substrate is electrically connected to the second conductivity type semiconductor layer. The transmissive substrate has the same polarity as the second conductivity type semiconductor layer. For this reason, an electrode for causing the light emission of the luminous layer can be formed on the transmissive substrate.

In one embodiment, the transmissive substrate is made of a first conductivity type semiconductor or a first conductivity type electric conductor.

In this embodiment, the transmissive substrate is not electrically connected with the second conductivity type semiconductor layer. When the transmissive substrate has been directly attached to the second type semiconductor layer, the interface between the transmissive substrate and the second type semiconductor layer becomes a p-n junction interface. Since a neutral region (depletion layer) is formed at the p-n junction interface, no current flows unless a certain voltage is applied.

For this reason, the light emission of the luminous layer can be caused by, for example, forming a contact layer between the transmissive substrate and the second conductivity type semiconductor layer and forming an electrode on the contact layer.

In one embodiment, the transmissive substrate is made of an insulator.

In this embodiment, the transmissive substrate is not electrically connected with the second conductivity type semiconductor layer.

For this reason, the light emission of the luminous layer can be caused by, for example, forming a contact layer between the transmissive substrate and the second conductivity type semiconductor layer and forming an electrode on the contact layer.

The first conductivity type semiconductor layer, the luminous layer, and the second conductivity type semiconductor layer may each contain at least two of gallium, aluminum, indium, phosphorus, arsenic, zinc, tellurium, sulfur, nitrogen, silicon, carbon, oxygen, magnesium, and selenium.

In this case, the emission wavelength of the luminous layer can be selected from a wide range of from the infrared region to the near-ultraviolet region.

A method of manufacturing a semiconductor light-emitting device according to another aspect of the present invention is intended for a semiconductor light-emitting device that includes a first conductivity type semiconductor layer, a luminous layer formed on the first conductivity type semiconductor layer, a second conductivity type semiconductor layer formed on the luminous layer, and a transmissive substrate which is formed on the second conductivity type semiconductor layer and is pervious to light coming from the luminous layer, wherein the second conductivity type semiconductor layer and the transmissive substrate have their respective carrier concentrations and the carrier concentration of the transmissive substrate is lower than the carrier concentration of the second conductivity type semiconductor layer. And, the method includes:

stacking the first conductivity type semiconductor layer, the luminous layer, and the second conductivity type semiconductor layer on a first conductivity type semiconductor substrate,

joining the transmissive substrate to the second conductivity type semiconductor layer directly or via a bonding material layer by heating the transmissive substrate while pressing the transmissive substrate against the second conductivity type semiconductor layer, and

removing the first conductivity type semiconductor substrate.

When the transmissive substrate is directly joined to the second conductivity type semiconductor layer, the resistance of the interface between the transmissive substrate and the second conductivity type semiconductor layer influences the driving voltage of the semiconductor light-emitting device. For this reason, the carrier concentration of the transmissive substrate is preferably 2.5×10¹⁸ cm⁻³ or less, and is particularly preferable between 5.0×10¹⁷ cm⁻³ and 10.0×10¹⁷ cm⁻³ inclusive.

When the carrier concentration of the transmissive substrate is set to 2.5×10¹⁸ cm⁻³ or less, the resistance of the interface between the transmissive substrate and the second conductivity type semiconductor layer can be reduced and the light transmittance of the transmissive substrate can be increased.

On the other hand, when the transmissive substrate is joined to the second conductivity type semiconductor layer via the bonding material layer, the temperature of heat treatment can be reduced as compared with that in the case that the transmissive substrate is directly bonded to the second conductivity type semiconductor layer.

The bonding material layer may be a transmissive material layer.

If the transmissive material layer is formed from, for example, indium tin oxide (ITO), the resistance of the interface between the transmissive material layer and the transmissive substrate decreases and therefore a transmissive substrate having a lower carrier concentration may be used.

Furthermore, a transparent bonding material layer may be laid on the second conductivity type semiconductor layer, and then the transmissive substrate may be bonded to the second conductivity type semiconductor layer via the transparent bonding material layer, or a transparent bonding material layer may be laid on the transmissive substrate and then the transmissive substrate may be bonded to the second conductivity type semiconductor layer via the transparent bonding material layer. In other words, the transmissive material layer may be formed on either the second conductivity type semiconductor layer or the transmissive substrate before the bonding of the transmissive substrate.

Furthermore, at least part of the transmissive material layer is required to be pervious to the light from the luminous layer.

The bonding material layer may be a metallic material layer. In this case, the transmissive substrate is bonded to the second conductivity type semiconductor layer via the metallic bonding material layer, so that the resistance of the interface between the metallic material layer and the transmissive substrate is reduced. As a result, a transmissive substrate having a lower carrier concentration may be used.

Furthermore, in order to allowing the light from the luminous layer to come into the transmissive substrate, the thickness of the metallic material layer may be 50 nm or less, or the shape of the metallic material layer may be set so as not to cover the whole of the luminous layer-side surface of the transmissive substrate.

### BRIEF DESCRIPTION OF THE DRAWINGS

The present invention will become more fully understood from the detailed description given hereinbelow and the accompanying drawings which are given by way of illustration only, and thus are not intended to limit the present invention, and wherein:

FIG. 1 is a schematic cross-sectional view of a conventional LED;

FIG. 2 is a schematic cross-sectional view of another conventional LED;

FIG. 3A is a graph showing the distribution in the depth direction of zinc concentration at the attaching interface of a GaP substrate having a high carrier concentration;

FIG. 3B is a graph showing the distribution in the depth direction of zinc concentration at the attaching interface of a GaP substrate having a low carrier concentration;

FIG. 4 is a graph showing the relation between the wavelength of light incident on a GaP substrate and the light transmittance of the GaP substrate;

FIG. 5 is a graph showing the relation between the light transmittance of a GaP substrate and the optical path length;

FIG. 6A shows the radiation pattern of a red semiconductor light-emitting device including a p-type GaP substrate having a high carrier concentration;

FIG. 6B shows the radiation pattern of a red semiconductor light-emitting device including a p-type GaP substrate having a low carrier concentration;

FIG. 7 is a schematic cross-sectional view of a jig used for manufacturing the semiconductor light-emitting devices of the first to third embodiments of the present invention;

FIG. 8 is a schematic cross-sectional view of the semiconductor light-emitting device of the first embodiment;

FIG. 9 is a schematic cross-sectional view of the semiconductor light-emitting device of the second embodiment; and

FIG. 10 is a schematic cross-sectional view of the semiconductor light-emitting device of the third embodiment.

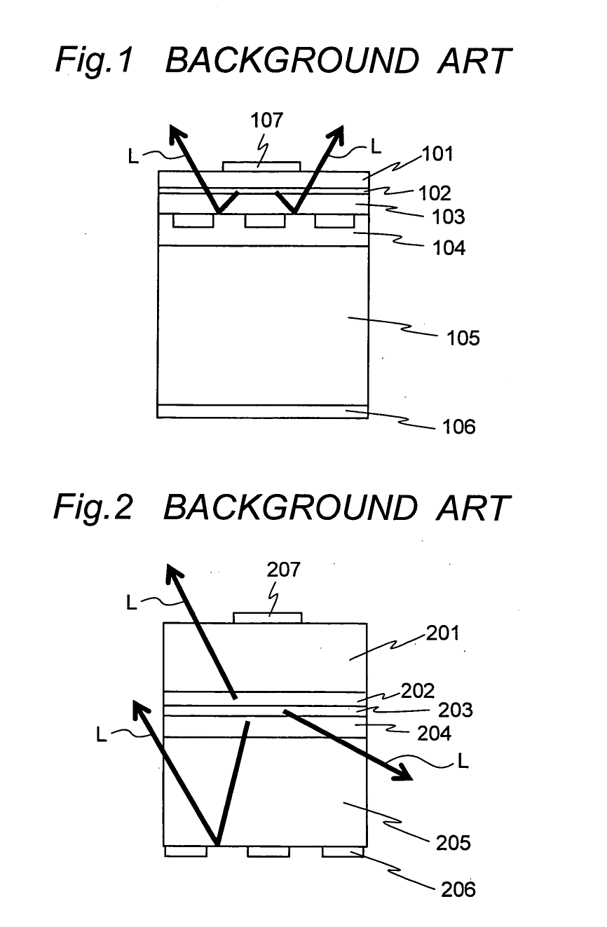

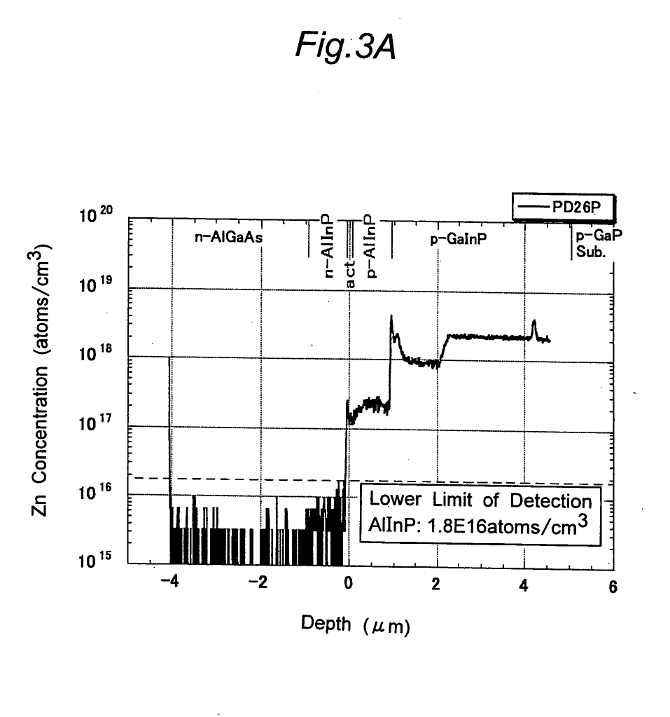

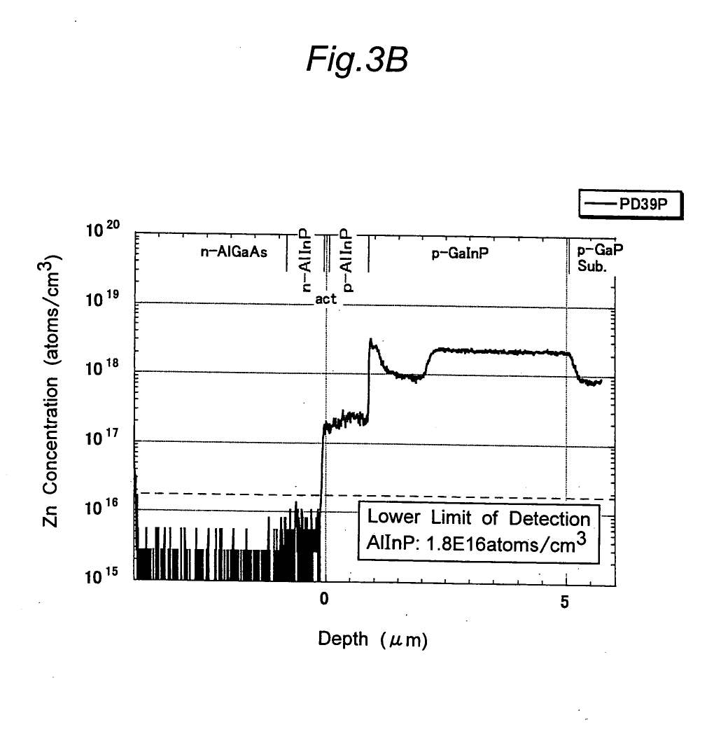

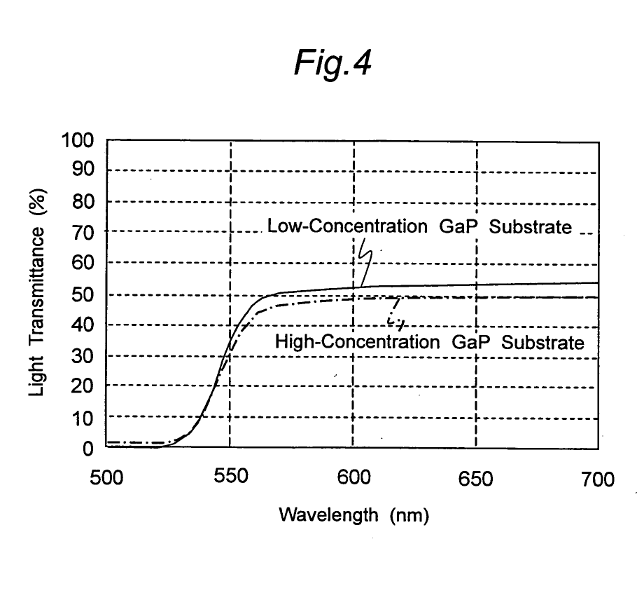

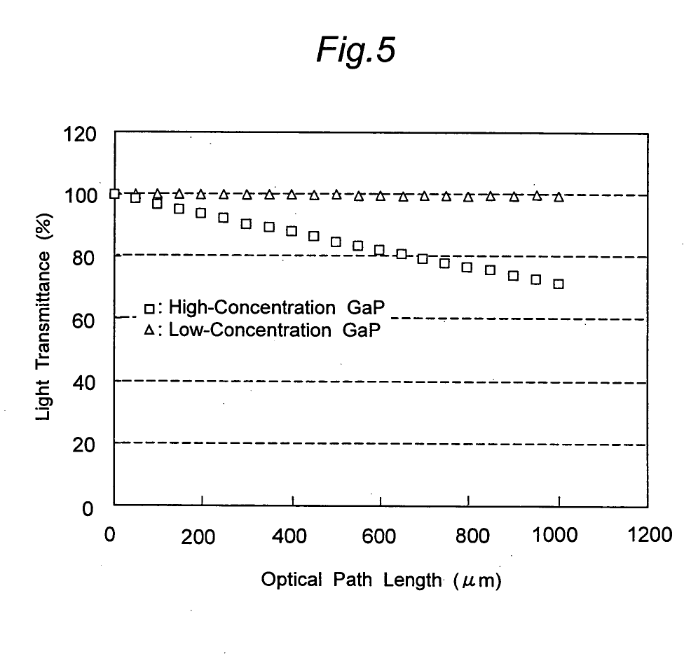

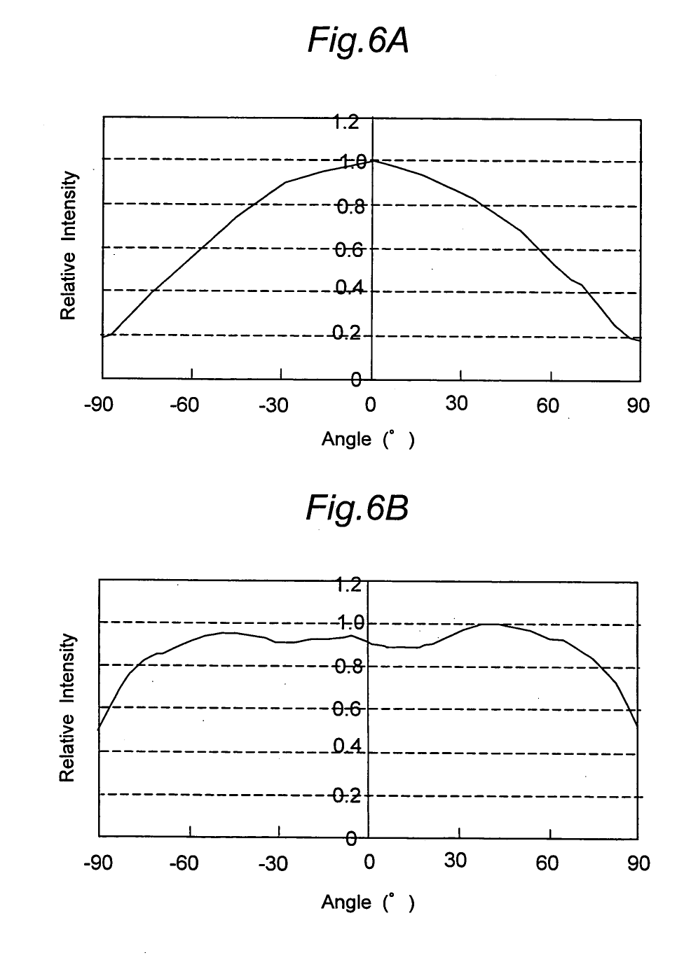

### DETAILED DESCRIPTION OF THE INVENTION

### First Embodiment

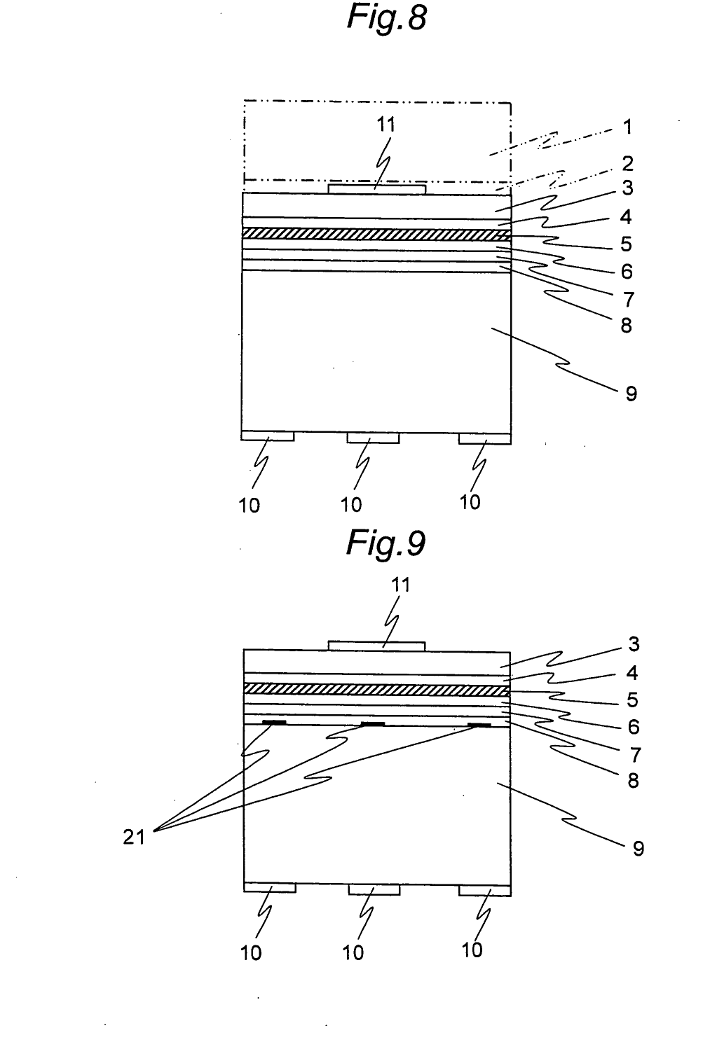

FIG. 8 is a schematic cross-sectional view of the semiconductor light-emitting device of the first embodiment of the present invention.

The semiconductor light-emitting device has an AlGaInP 4-element luminous layer 5 which has an emission wavelength for a red color. This AlGaInP luminous layer 5 is an example of the luminous layer.

The semiconductor light-emitting device further has an Al_{0.6}Ga_{0.4}As current diffusion layer (referred to as an “n-type AlGaAs current diffusion layer” hereinafter) 3 and an n-type Al_{0.5}In_{0.5}P cladding layer (referred to as an “n-type AlInP cladding layer” hereinafter) 4 which are positioned on the upper side, as viewed in the figure, of the AlGaInP luminous layer 5. The n-type AlGaAs current diffusion layer 3 and the n-type AlInP cladding layer 4 are an example of the first conductivity type semiconductor layer.

The semiconductor light-emitting device further has a p-type Al_{0.5}In_{0.5}P cladding layer (referred to as a “p-type AlInP cladding layer” hereinafter) 6, a p-type GaInP intermediate layer 7, and a p-type GaP contact layer 8 which are positioned under the AlGaInP luminous layer 5 in the figure. The p-type GaP contact layer 8 is an example of the second conductivity type semiconductor layer.

The semiconductor light-emitting device further has a p-type GaP light-transmissive substrate 9 attached to the p-type GaP contact layer 8. The p-type GaP light-transmissive substrate 9 is an example of the transmissive substrate. A light-transmissive substrate usable in the present invention is, of course, not limited to a GaP substrate, and may be a substrate at least part of which is formed of a semiconductor or electrically conductive material such as, for example, BN, AlP, AlN, AlAs, AlSb, GaN, SiC, ZnSe, ZnTe, CdS, ZnS, ITO, or ZnO, or may be a substrate at least part of which is formed of a 3 or more-element semiconductor or electrically conductive material which is composed of a compound crystal of semiconductor materials and/or electrically conductive materials.

A method of manufacturing the semiconductor light-emitting device will be described below.

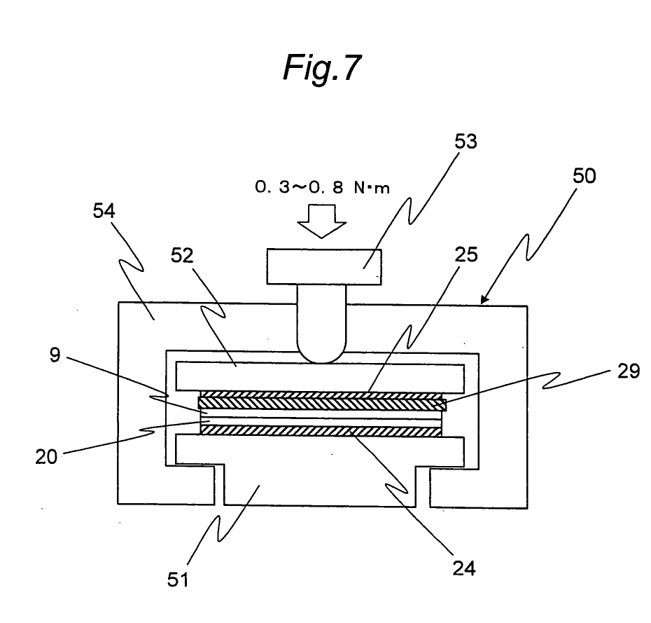

At first, an LED wafer 20 (see FIG. 7) is made in which an n-type GaAs buffer layer 2, an AlGaAs current diffusion layer 3, an n-type AlInP cladding layer 4, an AlGaInP active layer 5, a p-type AlInP cladding layer 6, a p-type GaInP intermediate layer 7 and a p-type GaP contact layer 8 are staked in this order on an n-type GaAs substrate 1 by a MOCVD method.

The AlGaInP active layer 5 has a quantum well structure. In more detail, the AlGaInP active layer 5 is formed by stacking alternately (Al_{0.5}Ga_{0.95})_{0.5}In_{0.5}P well layers and (Al_{0.5}Ga_{0.5})_{0.5}In_{0.5}P barrier layers. The number of pairs of the well layer and the barrier layer is 10.

Thicknesses of the above layers are: 250 μm of the n-type GaAs substrate 1, 1.0 μm of the n-type GaAs buffer layer 2, 5.0 μm of the AlGaAs current diffusion layer 3, 1.0 μm of the n-type AlInP cladding layer 4, 0.5 μm of the AlGaInP active layer 5, 1.0 μm of the p-type AlInP cladding layer 6, 1.0 μm of the p-type GaInP intermediate layer 7, and 4.0 μm of the p-type GaP contact layer 8.

In the layers, Si is used as an n-type dopant while Zn is used as a p-type dopant. As the n-type dopant of the layers, Se or the like, for example, other than Si may be used. As the p-type dopant of the layers, Mg, carbon, or the like, for example, other than Zn may be used. In other words, the n-type dopant of the layers is not limited to Si, and the p-type dopant of the layers is not limited to Zn.

Carrier concentrations of the layers are: 1.0×10¹⁸ cm⁻³ of the n-type GaAs substrate 1, 2.5×10¹⁷ cm⁻³ of the n-type GaAs buffer layer 2, 1.0×10¹⁸ cm⁻³ of the n-type AlGaAs current diffusion layer 3, 5×10¹⁷ cm⁻³ of the n-type AlInP cladding layer 4, the AlGaInP active layer 5 being non-doped, 5×10¹⁷ cm⁻³ of the p-type AlInP cladding layer 6, 1.0×10¹⁸ cm⁻³ of the p-type GaInP intermediate layer 7, and 2.0×10¹⁸ cm⁻³ of the p-type GaP contact layer 8.

Next, the wafer 20 is half-diced to form half-dicing grooves at a predetermined pitch on the epitaxial face of the wafer. The depth of the order of 10 to 50 μm of the half-dicing grooves is suitable to keep the strength of the LED wafer.

Next, a p-type GaP light-transmissive substrate 9 having a carrier concentration of 5.0×10¹⁷ cm⁻³ is directly attached to the wafer 20 using a jig 50 shown in FIG. 7.

The jig 50 is made of quartz and has a base 51 for supporting the wafer 20, a presser board 52 for covering an upper surface, as viewed in FIG. 7, of the p-type GaP light-transmissive substrate 9, and a pusher 53 for pushing the presser board 52 by receiving a predetermined magnitude of force.

The pusher 53 is adapted to be guided in the vertical direction by a frame 54 substantially shaped like the symbol] when viewed from the front side. The frame 54 is adapted to be engaged with the base 51 to transfer the force appropriately to the presser board 52 positioned between the base 51 and the pusher 53.

A carbon sheet 24 is disposed between the base 51 and the wafer 20, while a carbon sheet 25 and a pyrolytic boron nitride (PBN) board 29 are disposed between the presser board 52 and the p-type GaP light-transmissive substrate 9.

Using the jig 50, the wafer 20 and the p-type GaP light-transmissive substrate 9 are brought into contact with each other, and the moment of force of 0.3 Nm-0.8 Nm, for example, is applied to the pusher 53 in order that compressive force acts on the contact surface between the wafer 20 and the p-type GaP light-transmissive substrate 9. In this state, the wafer 20 and the p-type GaP light-transmissive substrate 9 are set in a heating furnace together with the jig 50 and are heated for 30 minutes at a temperature in the neighborhood of 800° C. in an atmosphere of hydrogen. As a result, the p-type GaP light-transmissive substrate 9 is directly joined to the wafer 20.

Next, the wafer 20 and the p-type GaP light-transmissive substrate 9 are cooled, and are then taken out from the heating furnace. After that, the n-type GaAs substrate 1 and the n-type GaAs buffer layer 2 are dissolved away with the mixture of ammonia water, hydrogen peroxide, and water. Other techniques of removing the n-type GaAs substrate 1 include a technique of removing the n-type GaAs substrate 1 by mechanical lapping, and a technique of peeling off the n-type GaAs substrate 1 from the n-type GaAs buffer layer 2, by applying laser light or the like to the interface between the n-type GaAs substrate 1 and the n-type GaAs buffer layer 2, to remove the n-type GaAs substrate 1.

Next, p-type electrodes 10 are formed on the p-type GaP light-transmissive substrate 9, while an n-type electrode 11 is formed on the AlGaAs current diffusion layer 3, and then dicing of the wafer is performed along the half-dicing grooves for chip splitting, to thereby obtain a semiconductor light-emitting device as shown in FIG. 8.

AuBe/Au is selected as the material of the p-type electrodes 10, while AuSi/Au is selected as the material of the n-type electrode 11. These materials are deposited on the wafer and patterned into predetermined shapes by photolithography and wet etching, to thereby obtain the p-type electrode 10 and the n-type electrode 11.

In the semiconductor light-emitting device obtained as described above, the carrier concentration of the p-type Gap light-transmissive substrate 9 is 5.0×10¹⁷ cm⁻³, so that the resistance of the interface between the p-type GaP light-transmissive substrate 9 and the p-type GaP contact layer 8 does not become high and therefore the driving voltage can be prevented from increasing.

Furthermore, since the carrier concentration of the p-type Gap light-transmissive substrate 9 is 5.0×10¹⁷ cm⁻³, Zn, which is a dopant, is not segregated to the interface between the p-type GaP light-transmissive substrate 9 and the p-type GaP contact layer 8, and therefore the light extraction efficiency can be increased.

In the first embodiment, because the n-type GaAs substrate 1 and the n-type GaAs buffer layer 2 absorb the light from the AlGaInP luminous layer 5, the n-type GaAs substrate 1 and the n-type GaAs buffer layer 2 have been removed. However, if an n-type substrate and an n-type buffer layer made of materials which do not absorb the light from the AlGaInP luminous layer 5 are used, they do not have to be removed.

Although the p-type GaP light-transmissive substrate 9 having the carrier concentration of 5.0×10¹⁷ cm⁻³ is used in the first embodiment, the carrier concentration of the p-type GaP light-transmissive substrate used in the present invention is not limited to 5.0×10¹⁷ cm⁻³. In other words, a p-type GaP light-transmissive substrate having a carrier concentration of 2.5×10¹⁸ cm⁻³ or less may be used in the present invention.

Among the preferable carrier concentration range of 2.5×10¹⁸ cm⁻³ or less for the p-type GaP light-transmissive substrate, a carrier concentration within a range of from 5.0×10¹⁷ cm⁻³ to 10.0×10¹⁷ cm⁻³ is particularly preferable.

Although the p-type GaP contact layer 8 having the carrier concentration of 2.0×10¹⁸ cm⁻³ is used in the first embodiment, the carrier concentration of a p-type GaP contact layer used in the present invention is not limited to 2.0×10¹⁸ cm⁻³. In other words, a p-type GaP contact layer having a carrier concentration in a range of between 5.0×10¹⁷ cm⁻³ and 5.0×10¹⁸ cm³ may be used in the present invention.

### Second Embodiment

FIG. 9 is a schematic cross-sectional view of the semiconductor light-emitting device of the second embodiment of the present invention. Components shown in FIG. 9 that are made of the same materials as those of the first embodiment shown in FIG. 8 are denoted by the same reference numbers as those of the components in FIG. 8.

The semiconductor light-emitting device of the second embodiment is different from the semiconductor light-emitting device of the first embodiment in that the carrier concentration of the p-type GaP light-transmissive substrate 9 is less than 5.0×10¹⁷ cm⁻³ and that a metallic layer 21 is formed between the p-type GaP light-transmissive substrate 9 and the p-type GaP contact layer 8 in the second embodiment.

When the semiconductor light-emitting device is manufactured, the wafer 20 is prepared as with the first embodiment, but it is not necessary to form half-dicing grooves on the wafer 20 in advance.

In the method of manufacturing the semiconductor light-emitting device, a thin film made of gold, silver, aluminum, titanium or a compound thereof or an alloy thereof is formed to a thickness of 100 nm on the epitaxial surface (which is a surface on the p-type GaP light-transmissive substrate 9 side) of the wafer 20 or on the attaching surface of the p-type GaP light-transmissive substrate 9 by a vapor deposition method or a sputtering method.

Next, the thin film is patterned into a predetermined shape by a photolithographic method and wet etching to obtain the metallic layer 21. If the thickness of the metallic layer 21 is 50 nm or less so that the metallic layer 21 allows light coming from the luminous layer to pass through the metallic layer 21 into the p-type light-transmissive substrate 9, the metallic layer 21 can be formed over the entire attaching surface of the p-type light-transmissive substrate 9. In such a case, the patterning process for the metallic layer 21 is dispensed with.

The area of an AlGaInP luminous layer 5-side surface of the metallic layer 21 is set to 10% or less of the area of an AlGaInP luminous layer 5-side surface of the p-type GaP light-transmissive substrate 9. Because of this, the loss of light on the AlGaInP luminous layer 5-side surface of the p-type GaP light-transmissive substrate 9 can be kept to a minimum. The metallic layer 21 is an example of the metallic bonding material layer.

Next, the attaching of the p-type Gap light-transmissive substrate 9, the removing of the substrate and the buffer layer, and the chip splitting are performed as with the first embodiment to thereby obtain the semiconductor light-emitting device as shown in FIG. 9.

When the p-type Gap light-transmissive substrate 9 is bonded to the p-type GaP contact layer 8 via the metallic layer 21 like this embodiment, this can be accomplished by performing a heat treatment for 30 minutes at a temperature in the neighborhood of 500° C. in an atmosphere of hydrogen.

### Third Embodiment

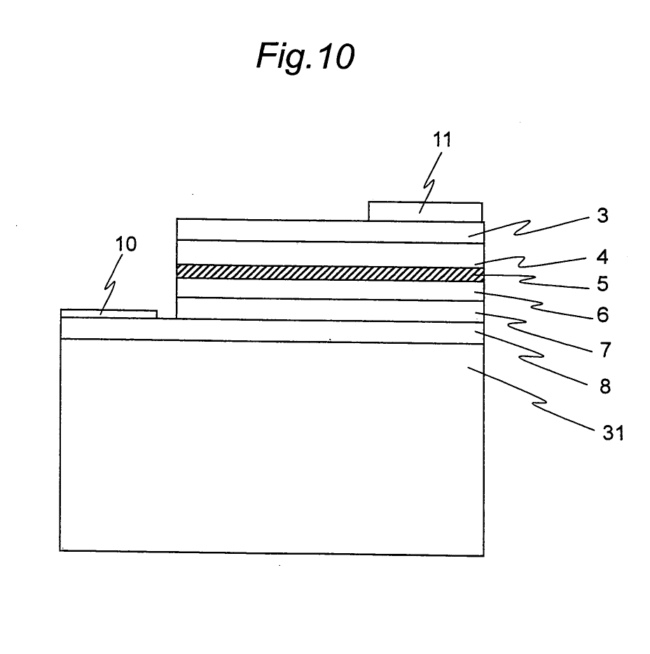

FIG. 10 is a schematic cross-sectional view of the semiconductor light-emitting device of the third embodiment of the present invention. Components shown in FIG. 10 that are made of the same materials as those of the first embodiment shown in FIG. 8 are denoted by the same reference numbers as those of the components in FIG. 8.

The semiconductor light-emitting device of the third embodiment is different from the first embodiment in that the device of the third embodiment has a light-transmissive substrate 31 made of an insulator. As the insulator, materials such as, for example, Al₂O₃, SiO₂, glass, insulative semiconductors, SiC, GaP, ZnO, TiO₂, and SnO₂ are usable.

The light-transmissive substrate 31 is pervious to the light coming from the AlGaInP luminous layer 5. In other words, the light-transmissive substrate 31 is made of insulating material which is transparent to the emission wavelength of the AlGaInP luminous layer 5. The light-transmissive substrate 31 is an example of the transmissive substrate.

The method of manufacturing the semiconductor light-emitting device of the third embodiment is different from that of the first embodiment in that after the substrate and the buffer layer have been removed, part of the epitaxial layers is etched off so that the p-type GaP contact layer 8 is partially exposed, and a p-type electrode 10 is formed on the exposed p-type GaP contact layer 8.

By forming the p-type electrode 10 on the p-type GaP contact layer 8, the electric current is allowed to pass through only the epitaxial layers.

Although the light-transmissive substrate 31 made of insulator is used as an example of the transmissive substrate in the third embodiment, an n-type GaP substrate having a carrier concentration of less than 5.0×10¹⁷ cm⁻³, for example, a carrier concentration of 5.0×10¹⁶ cm⁻³, may be used as an example of the transmissive substrate, instead of the light-transmissive substrate 31.

When an n-type GaP substrate having the carrier concentration of 5.0×10¹⁶ cm⁻³ is used, the epitaxial surface is not electrically connected to the n-type GaP substrate by an ordinary LED driving voltage (10 V or less).

Although the light-transmissive substrate 31 made of insulator is used as an example of the transmissive substrate in the third embodiment, a p-type light-transmissive substrate made of a semiconductor or conductive material which is pervious to the light coming from the AlGaInP luminous layer 5 may be used as an example of the transmissive substrate instead of the light-transmissive substrate 31.

The present invention is also applicable to semiconductor light-emitting devices having conductivity types which are opposite to those of the first to third embodiments.

It is needless to say that the present invention is applicable to not only a light-emitting diode having a AlGaInP 4-element luminous layer but also a semiconductor light-emitting device having a luminous layer made of semiconductor crystal.

Furthermore, materials and techniques to be used in the present invention are not limited to those of the first to third embodiments, and any suitable material and technique may be used in the present invention.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor light-emitting device, comprising:
a first conductivity type semiconductor layer;
a luminous layer formed on the first conductivity type semiconductor layer;
a second conductivity type semiconductor layer formed on the luminous layer; and
a transmissive substrate which is formed on the second conductivity type semiconductor layer and is pervious to light coming from the luminous layer, wherein
the second conductivity type semiconductor layer and the transmissive substrate have their respective carrier concentrations and the carrier concentration of the transmissive substrate is lower than the carrier concentration of the second conductivity type semiconductor layer.

2. A semiconductor light-emitting device as claimed in claim 1, wherein the carrier concentration of the transmissive substrate is 2.5×10¹⁸ cm⁻³ or less.

3. A semiconductor light-emitting device as claimed in claim 1, wherein the carrier concentration of the second conductivity type semiconductor layer is between 5.0×10¹⁷ cm⁻³ and 5.0×10¹⁸ cm⁻³, inclusive.

4. A semiconductor light-emitting device as claimed in claim 1, wherein at least part of the transmissive substrate is made of a second conductivity type semiconductor or a second conductivity type electric conductor.

5. A semiconductor light-emitting device as claimed in claim 1, wherein the transmissive substrate is made of a first conductivity type semiconductor or a first conductivity type electric conductor.

6. A semiconductor light-emitting device as claimed in claim 1, wherein the transmissive substrate is made of an insulator.

7. A semiconductor light-emitting device as claimed in claim 1, wherein the first conductivity type semiconductor layer, the luminous layer, and the second conductivity type semiconductor layer each contain at least two of gallium, aluminum, indium, phosphorus, arsenic, zinc, tellurium, sulfur, nitrogen, silicon, carbon, oxygen, magnesium, and selenium.

8. A method of manufacturing a semiconductor light-emitting device, said semiconductor light-emitting device comprising a first conductivity type semiconductor layer, a luminous layer formed on the first conductivity type semiconductor layer, a second conductivity type semiconductor layer formed on the luminous layer, and a transmissive substrate which is formed on the second conductivity type semiconductor layer and is pervious to light coming from the luminous layer, wherein the second conductivity type semiconductor layer and the transmissive substrate have their respective carrier concentrations and the carrier concentration of the transmissive substrate is lower than the carrier concentration of the second conductivity type semiconductor layer, the method comprising:
stacking the first conductivity type semiconductor layer, the luminous layer, and the second conductivity type semiconductor layer on a first conductivity type semiconductor substrate,
joining the transmissive substrate to the second conductivity type semiconductor layer directly or via a bonding material layer by heating the transmissive substrate while pressing the transmissive substrate against the second conductivity type semiconductor layer, and
removing the first conductivity type semiconductor substrate.

9. A method of manufacturing a semiconductor light-emitting device as claimed in claim 8, wherein the transmissive substrate is joined to the second conductivity type semiconductor layer via a transmissive material layer as the bonding material layer.

10. A method of manufacturing a semiconductor light-emitting device as claimed in claim 8, wherein the transmissive substrate is joined to the second conductivity type semiconductor layer via a metallic material layer as the bonding material layer.
